(19) United States
(12) Patent Application Publication
(10) Pub. No.: US 2025/0029888 A1
(43) Pub. Date: Jan. 23, 2025

(54) Customized heat dissipation from different types of integrated circuit dies packaged on a common substrate

(71) Applicant: Marvell Asia Pte Ltd, Singapore (SG)

(72) Inventors: Carl E. Benes, Waterbury, VT (US); Meenakshi Upadhyaya, Stanford, CA (US); Joshua F. Dillon, Stowe, VT (US); Andrew Killorin, Essex Junction, VT (US); Eric William Tremble, Jericho, VT (US); Wolfgang Sauter, Starksboro, VT (US)

(21) Appl. No.: 18/775,002

(22) Filed: Jul. 17, 2024

Related U.S. Application Data
(60) Provisional application No. 63/527,329, filed on Jul. 17, 2023.

(51) Int. Cl. H01L 23/367; H01L 21/48; H01L 23/10; H01L 25/065

(52) U.S. Cl. CPC H01L 23/3672; H01L 21/4803; H01L 21/4882; H01L 23/10; H01L 25/0655

(57) ABSTRACT

An electronic device includes: (i) first and second integrated circuit (IC) dies co-located on a surface of a substrate in proximity to each other, (ii) a heat sink disposed on the first and second IC dies, and (iii) a lid, which is disposed between the first IC die and the heat sink, and the lid is not disposed between the second IC die and the heat sink.

### CROSS-REFERENCE TO RELATED APPLICATIONS

This application claims the benefit of U.S. Provisional Patent Application 63/527,329, filed Jul. 17, 2023, whose disclosure is incorporated herein by reference.

### FIELD OF THE DISCLOSURE

The present invention relates generally to packaging of electronic devices, and particularly to methods and systems for customizing heat dissipation from integrated circuit (IC) dies integrated in a common package and operating at different temperatures.

### BACKGROUND

Some electronic devices comprise two or more different types of IC dies integrated in a common package having a predefined planarity specification. Moreover, in some cases, each type of the IC dies is designed to operate at different temperatures. A package that integrates such devices is required (i) to comply with the planarity requirements, and (ii) to dissipate the heat generated by the different types of IC dies at different heat dissipation rates.

The description above is presented as a general overview of related art in this field and should not be construed as an admission that any of the information it contains constitutes prior art against the present patent application.

### SUMMARY

An embodiment of the present invention that is described herein provides an electronic device including (i) first and second integrated circuit (IC) dies co-located on a surface of a substrate in proximity to each other, (ii) a heat sink disposed on the first and second IC dies, and (iii) a lid, which is disposed between the first IC die and the heat sink, the lid is not disposed between the second IC die and the heat sink.

In some embodiments, the first IC die has (i) a first side, and (ii) a plurality of second sides, the second IC die is positioned to face the first side of the first IC die, and the lid is positioned to face at least one of the second sides of the first IC die. In other embodiments, the heat sink has a stepped structure including: (i) a first surface configured to dissipate heat from the lid, and (ii) a second surface stepped from the first surface and configured to dissipate heat from the second die. In yet other embodiments, the first and second IC dies are positioned side-by-side on the surface of the substrate, and the heat sink includes a connection section connecting between the first surface and the second surface of the stepped structure, and at least a portion of the connection section is placed in contact with the lid.

In some embodiments, the first IC die is configured to operate at a first temperature, and the second IC die is configured to operate at a second temperature, different from the first temperature, and the electronic device includes (i) a first thermal interface material (TIM) disposed between the first IC die and the lid, (ii) a second TIM disposed between the second IC die and the heat sink, the first and second TIMs are separated from one another, and (iii) a structure formed between the first and second IC dies, and configured to reduce heat transfer between the first IC die and the second IC die.

In other embodiments, the electronic device includes a dam structure disposed between the first TIM and the second TIM, the dam structure being configured to reduce material transfer between the first TIM and the second TIM. In yet other embodiments, the lid has a confining section disposed between the first TIM and the second TIM, the confining section being configured to reduce material transfer between the first TIM and the second TIM.

In some embodiments, the electronic device includes a groove formed in the structure between the first IC die and the second IC die, the groove is configured to reduce heat transfer between the first IC die and the second IC die. In other embodiments, the confining section of the lid is shaped to fit in at least part of the groove. In yet another embodiment, the confining section of the lid is configured to self-align with the groove.

There is additionally provided, in accordance with an embodiment of the present invention, a method for fabricating an electronic device, the method including disposing, on a surface of a substrate, first and second integrated circuit (IC) dies co-located on the surface in proximity to each other. A heat sink is disposed on the first and second IC dies, and a lid, which is (i) disposed between the first IC die and the heat sink, and (ii) not disposed between the second IC die and the heat sink.

The present disclosure will be more fully understood from the following detailed description of the embodiments thereof, taken together with the drawings in which:

### BRIEF DESCRIPTION OF THE DRAWINGS

FIG. 1 is a schematic, sectional view of an electronic device comprising several types of IC dies integrated in a common package, in accordance with an embodiment that is described herein;

FIG. 2 is a schematic, sectional view of an electronic device comprising several types of IC dies integrated in a common package, in accordance with another embodiment that is described herein;

FIG. 3 is a schematic, sectional view of an electronic device comprising several types of IC dies integrated in a common package, in accordance with an alternative embodiment that is described herein; and

FIG. 4 is a flow chart that schematically illustrates a method for fabricating the electronic device of FIG. 3, in accordance with an embodiment that is described herein.

### DETAILED DESCRIPTION OF EMBODIMENTS

Some electronic devices comprise different types of IC dies integrated in a common package and co-located adjacent to one another on a common substrate. For example, an electronic device may comprise (i) an application-specific IC (ASIC), and (ii) a high bandwidth memory (HBM) comprising a stack of multiple memory devices. The ASIC is designed to operate at a temperature of at least 105° C. (e.g., between about 105° C. and 125° C.), and the HBM is designed to operate at a temperature of at least 85° C. (e.g., between about 85° C. and 95° C.). The ASIC and HBM are placed side-by-side on an interposer (made from silicon or from any other suitable material) and may have different thicknesses. It is noted that a package of an electronic device comprising different IC dies having different thicknesses and different operating temperatures, may cause (i) a warpage of the package, and (ii) overheating of the ASIC due to insufficient rate of heat dissipation, which may result in failures during the operation of the electronic device.

Embodiments of the present disclosure that are described herein provide techniques for improving the planarity and heat dissipation in electronic devices comprising different types of IC dies having different or equivalent thicknesses and operating at different temperatures.

In some embodiments, an electronic device comprises the aforementioned ASIC and HBM are co-located on a surface of a suitable substrate, or the interposer described above adjacent to one another (e.g., side-by-side). The HBM has a first side, and a plurality of second sides.

In some embodiments, the electronic device comprises a heat sink disposed on the ASIC and the HBM, and a lid, which is disposed between the HBM and the heat sink. The HBM comprises a plurality of memory devices stacked on one another, and the lid is configured to stiffen the package of the HBM, and to dissipate heat from the HBM to the heat sink. As such, in the context of the present disclosure and in the claims the term lid is also referred to herein as stiffener, or stiffening structure. In the present example, the ASIC is positioned to face the first side of the HBM, and the lid is positioned to face at least one of the second sides of the HBM. Moreover, the electronic device comprises a layer of dielectric material disposed on the interposer surface for electrically insulating between the ASIC and the HBM.

As described above, the ASIC operates at higher temperatures, and therefore, requires a higher rate of heat dissipation compared to that of the HBM.

In some embodiments, the heat sink has a stepped structure comprising: (i) a first surface configured to dissipate heat from the lid, and (ii) a second surface, stepped from the first surface, and configured to dissipate heat from the ASIC. In such embodiments, the lid is not disposed between the ASIC and the heat sink, so that the heat generated by the ASIC is being dissipated directly to the heat sink, and therefore, at a higher dissipation rate compared to that of the HBM.

In some embodiments, the electronic device comprises layers of thermal interface material (TIM) disposed between (i) the ASIC and the heat sink, (ii) the HBM and the lid, and (iii) the lid and the heat sink. The TIM layers are configured to improve the heat transfer from the IC dies to the lid and heat sink. In such embodiments, at least two of the aforementioned TIM layers may have a different thickness and/or a different heat conductivity from one another.

The different heat generated by the ASIC and the HBM may cause leakage, also referred to as creeping, of the ITM between the IC dies. For example, due to the higher operating temperature of the ASIC, a first TIM layer disposed between the ASIC and the heat sink may creep toward a second TIM layer disposed between the HBM and the lid. This creeping may result, for example, in overheating of the ASIC due to insufficient heat transfer rate between the ASIC and the heat sink.

In some embodiments, the electronic device comprises a dam structure disposed at least between the first and second TIM layers. The dam structure is configured to reduce material transfer between the TIM layers, and more specifically, to prevent the aforementioned creeping of the TIM layers. The dam structure may comprise a suitable type of dielectric material. Alternatively, the dam structure may comprise a confining metal section of the lid, which is extended to separate between the TIM layers.

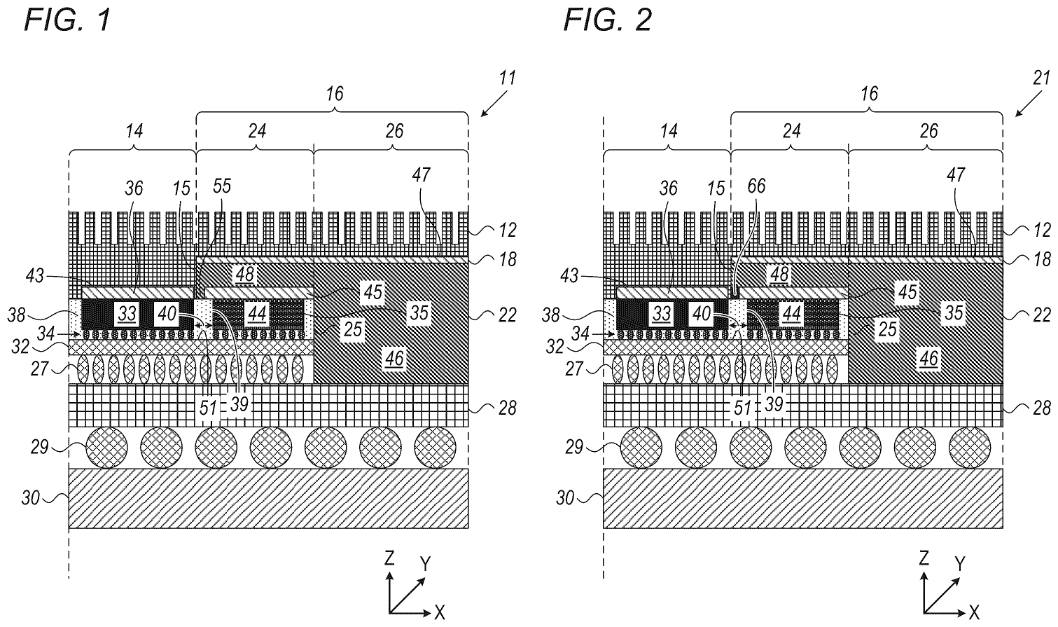

In some embodiments, the electronic device has a groove formed in the dielectric layer between the ASIC and the HBM. The groove is configured to reduce transfer of heat between the ASIC and the HBM. It is noted that most of the heat is transferred vertically, but the groove reduces lateral transfer of the heat. The groove may be filled with air and/or with the confining metal section of the lid. In the latter configuration, the confining metal section is configured to dissipate the heat toward the heat sink. The structure of the electronic device, and the dam structure, groove, and confining structure are described in more detail in FIGS. 1, 2 and 3 below.

The description above is presented as a general overview of embodiments of the present disclosure, which are described in detail herein.

FIG. 1 is a schematic, sectional view of an electronic device 11, in accordance with an embodiment that is described herein. Electronic device 11 is also referred to herein as a device 11 for brevity.

In embodiments, some device 11 comprises different types of IC dies integrated in a common package. In the present example, device 11 comprises an application-specific IC (ASIC) 33 and a high bandwidth memory (HBM) 44 comprising a stack of multiple memory devices, such as dynamic random-access memory (DRAM) devices. ASIC 33 is configured to operate at temperature of at least 105° C. (e.g., up to about 125° C., and HBM 44 is configured to operate at a temperature between about 85° C. and 95° C. The higher operating temperatures of ASIC 33 require a higher rate of heat dissipation compared to that of HBM 44. ASIC 33 and HBM 44 are disposed on a surface 51 of a silicon interposer 32 in propinquity to each other at a distance 40 (e.g., between about 2 mm and 20 mm). In the context of the present disclosure and in the claims, the terms proximity, propinquity, and adjacent, and grammatical variations thereof are used interchangeably.

In some embodiments, device 11 comprises a laminate substrate 28 and a lid 22 typically made from copper and mounted on laminate substrate 28. Lid 22 is configured to (i) stiffen at least a portion of device 11, and (ii) dissipate heat from at least HBM 44, as will be described in detail below. In the present example, the size of the package of electronic device 11 is approximately 100 mm along the X-axis and along the Y-axis of the XYZ coordinate system. As such, lid 22 is configured to improve the stiffness of the package, ad more specifically to improve the flatness of interposer 32 and the IC dies (e.g., ASIC 33 and HBM 44) co-located on surface 51 of interposer 32.

In some embodiments, laminate substrate 28 is mounted on a printed circuit board (PCB) 30 of device 11. Moreover, electronic device 11 comprises copper micro-bumps 34 configured for electrical coupling between (a) ASIC 33 and interposer 32, and (b) HBM 44 and interposer. Electronic device 11 further comprises (i) controlled collapse chip connection (C4) bumps 27 configured for electrical coupling between interposer 32 and laminate substrate 28, and a ball-grid array (BGA) 29 configured for electrical coupling between laminate substrate 28 and PCB 30.

In some embodiments, HBM 44 has a first side 39, and a plurality of second sides 35. In the present example, ASIC 44 is positioned to face the first side 39 of HBM 44, and the lid 22 is positioned to face at least one of the second sides 35 of HBM 44. The number of sides 35 facing lid 22 is typically between one and three, depending on the number of IC dies co-located with HBM 44 on surface 51. In the example of FIG. 1, lid 22 has a wall 25 facing and surrounding the second sides 35 of HBM 44. It is noted that an increased number of sides 35 facing lid 22 increases the stiffness of the package of device 11, and thereby, increases the flatness of at least interposer 32 and increases the coplanarity of ASIC 33 and HBM 44, which improves the electronic performance and the reliability of electronic device 11. Moreover, electronic device 11 comprises a layer 38 of dielectric material disposed on surface 35 of interposer 32. Layer 38 is configured to electrically insulate between ASIC 33 and HBM 44.

In some embodiments, device 11 comprises a heat sink 12 disposed on ASIC 33 and on HBM 44, and lid 22 is disposed between HBM 44 and heat sink 12. In the present configuration, lid 22 is configured to stiffen the package of HBM 44, and to transfer the heat from HBM 44 to heat sink 12.

In some embodiments, electronic device 11 comprises a plurality of thermal interface material (TIM) layers disposed between the IC dies and the lid and heat sink, and between the lid and the heat sink. In the present example, (i) a TIM layer 36 disposed between ASIC 33 and heat sink 12, (ii) a TIM layer 45 disposed between HBM 44 and lid 22, and (iii) a TIM layer 18 disposed between lid 22 and heat sink 12. In this configuration, TIM layers 36, 45 and 18 are configured to improve the heat transfer from ASIC 33 and HBM 44, to lid 22 and to heat sink 12. In such embodiments, at least two of TIM layers 36, 45 and 18 may have a different thickness and/or a different heat conductivity from one another. For example, TIM layer 36 may have higher thermal conductivity compared to that of TIM layer 45, in order to dissipate the larger amount of heat generated by ASIC 33 compared to that of HBM 44.

In some embodiments, heat sink 12 has a stepped structure comprising (i) a surface 47 configured to dissipate heat from lid 22, and (ii) a surface 43, which s stepped from surface 47, and is configured to dissipate heat from ASIC 33. It is noted that lid 22 is not disposed between ASIC 33 and heat sink 12, so that the heat generated by ASIC 33 being dissipated directly to heat sink 12, and therefore, at a higher dissipation rate compared to the heat generated by HBM 44.

The different heat generated by ASIC 33 and HBM 44 may cause transfer of at least a portion of at least one TIM layer, referred to herein as creeping, between ASIC 33 and HBM 44. For example, due to the operating temperature of ASIC 33 (e.g., between 105° C. and 125° C.), which is higher than that of HBM 44 (e.g., between 85° C. and 95° C.), TIM layer 36 may creep along the X-axis of the XYZ coordinate system, toward TIM layer 45 disposed between HBM 44 and lid 22. The creeping of TIM layer 36 may result, for example, in overheating of ASIC 33 because the rate of heat transfer between ASIC 33 and heat sink 12 may be insufficient to control the temperature required for operation of ASIC 33.

In some embodiments, lid 22 has a stepped structure comprising (i) a section 46, which is disposed between laminate substrate 28 and heat sink 12, and is configured to stiffen the packaging of HBM 44 in device 11, and (ii) a section 48, which is stepped from section 46, and is configured to dissipate heat between HBM 44 and heat sink 12. In the present example, section 48 is placed in contact with TIM layer 45, which is disposed on HBM 44 as described above.

In some embodiments, the stepped structure of heat sink 12 comprises a section 14 disposed on surface 43 of TIM layer 36 for dissipating heat generated mainly by ASIC 33. Moreover, a wall 15 of section 48 of lid 22 is placed in contact with section 14 of heat sink 12. In some embodiments, a section 16 of heat sink 12 is disposed on surface 47 of lid 22. Section 16 comprises (i) a subsection 24 disposed on section 48 of lid 22 and configured to dissipate heat generated mainly by HBM 44, and (ii) a sub-section 26 disposed on section 46 of lid 22 and configured to dissipate a portion of the heat generated by HBM 44.

In some embodiments, at least one of: (i) the arrangement of ASIC 33 and HBM 44 and the planarity of the package, and (ii) the size and the shape of lid 22 and/or heat sink 12, may be altered for optimizing the electrical performance of device 11, and for dissipating the heat generated by at least ASIC 33 and HBM 44. In such embodiments, heat sink 12 may comprise any other suitable number of sections arranged in any suitable configuration to increase the dissipation rate of heat away from ASIC 33 and HBM 44. For example, the size of sub-section 26 in X-AND Y-axis may be reduced, so that sub-section 26 will be smaller compared to that of section 14, so as to increase the dissipation rate of heat away from ASIC 33.

In some embodiments, electronic device 11 comprises a dam structure 55 disposed between TIM layers 36 and 45. In the present example, dam structure 55 is an extension of section 48, and therefore, made from copper. In this configuration, dam structure 55 is configured to reduce material transfer between the TIM layers, and more specifically, to prevent the creeping of TIM layer 36 toward TIM layer 45 as described above.

FIG. 2 is a schematic, sectional view of an electronic device 21 comprising ASIC 33 and HBM 44 co-located on interposer 32, in accordance with another embodiment that is described herein.

In some embodiments, the configuration of electronic device 21 is similar to that of electronic device 11 of FIG. 1 above, but instead of dam structure 55, electronic device 21 comprises a dam structure 66. In the present example, dam structure 66 is not part of lid 22, and is made from silicone elastomer adhesive, such as MasterSil 800 product supplied by MasterBond (154 Hobart Street Hackensack, NJ 07601), or from any other suitable material such as but not limited to epoxy or other suitable polymers configured to endure heat up to a temperature of about 125° C. (e.g., without being softened and/or undergoing plastic deformation and/or creeping). For example, the MasterSil 800 product is configured to operate at a broad range of temperatures, between about −75° C. and 300° C. In such embodiments, dam structure 66 is disposed between (i) section 48 of lid 22 and (ii) layer 38 and is configured to prevent the creeping of TIM layer 36 toward TIM layer 45 as described in detail in FIG. 1 above.

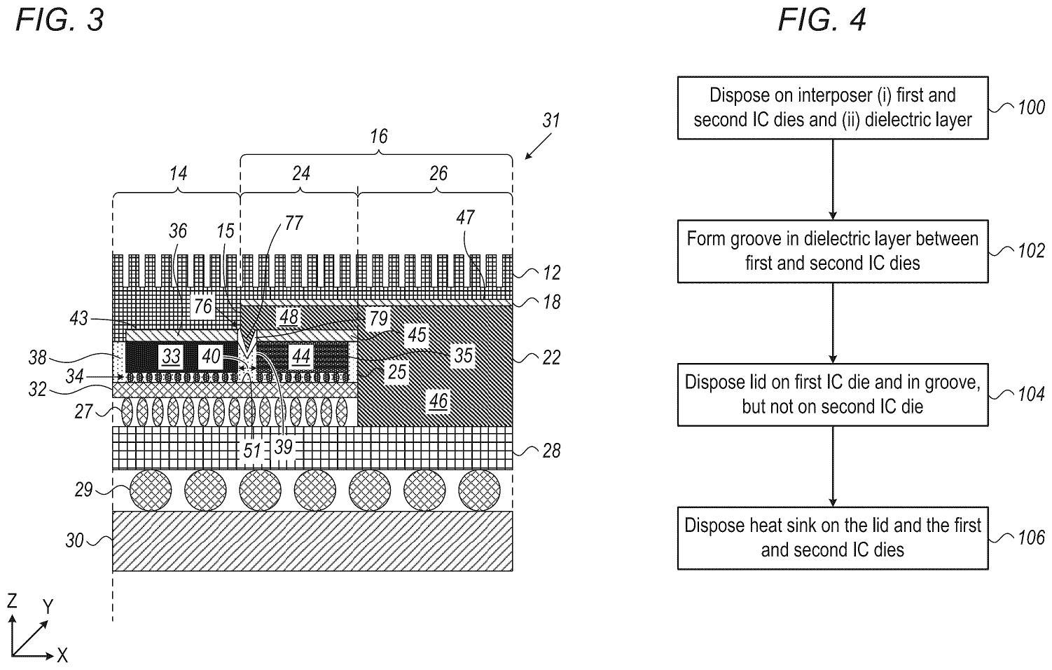

FIG. 3 is a schematic, sectional view of an electronic device 31 comprising ASIC 33 and HBM 44 co-located on interposer 32, in accordance with an alternative embodiment that is described herein.

In some embodiments, electronic device 31 has a groove 76 formed in dielectric layer 38 between ASIC 33 and HBM 44. Groove 76 is configured to reduce transfer of heat between ASIC 33 and HBM 44, for example, some of the heat generated by ASIC 33 (which operates at a higher temperature as described above) may be transferred through layer 38 and increase the temperature of HBM 44. It is noted that most of the heat is typically transferred vertically, i.e., along the Z-axis of device 31, but groove 76 is configured to reduce the lateral component of the heat transfer between ASIC 33 and HBM 44.

In some embodiments, groove 76 may be filled with air and/or with any suitable material configured to (i) reduce the lateral component of heat transferred between ASIC 33 and HBM 44, or (ii) dissipate the heat toward heat sink 12. In the present example, groove 76 is filled with air 79 and with a confining section 77 of lid 22, which is made from the same metal of lid 22. In this configuration, air 79 is configured to reduce the heat transfer, and the confining section 77 is configured to conduct the heat away from ASIC 33 and HBM 44, and to dissipate the heat toward heat sink 12.

In some embodiments, both groove 76 and confining section 77 have a wedge shape, and the volume of the wedge of groove is larger than that of confining section 77. In such embodiments, confining section 77 is self-aligned into groove 76 when disposing lid over laminate substrate 28 and HBM 44.

In other embodiments, the entire volume of groove 76 may be filled with air 79. The air gap between ASIC 33 and HBM 44 improves the thermal insulation and heat transfer between ASIC 33 and HBM 44.

In alternative embodiments, the entire volume of groove 76 may be filled with confining section 77 of lid 22. In alternative embodiments, device 31 may comprise a confining structure instead of confining section 77. The confining structure may be coupled to section 48 of lid 22, and may comprise a heat conductive material other than that of lid 22.

In the present example, all other components and layers of electronic device 31 are similar to that of electronic device 11 described in FIG. 1 above, but in other embodiments, device 31 may comprise at least one component and/or layer different from or in addition to the components and layers of device 11 described in FIG. 1 above. For example, instead of or in addition to at least one of ASIC 33 and HBM 44, electronic device 31 may comprise any other suitable IC die(s), such as but not limited to a three-dimensional package of multiple IC dies, and a III-V based semiconductor device.

These particular configurations of electronic devices 11, 21 and 31 are shown by way of example, in order to illustrate certain problems that are addressed by embodiments of the present invention and to demonstrate the application of these embodiments in enhancing the performance of such electronic devices. Embodiments of the present invention, however, are by no means limited to this specific sort of example electronic devices, and the principles described herein may similarly be applied to other sorts of electronic devices.

In other embodiments, at least one of electronic devices 11, 21 and 31 may comprise one or more additional heatsinks. For example, an additional heatsink may be disposed on TIM layer 36 instead of section 14 of heatsink 12. In such embodiments, the additional heatsink comprises a high performing liquid cooled block configured to dissipate the heat generated by ASIC 33 at a higher rate compared to that of heatsink 12 which is cooled by air (and is also referred to herein as a mass airflow heatsink). In other words, heatsink 12 is cooled by airflow and configured to dissipate the heat generated by HBM 44, and the additional heatsink is cooled by a suitable fluid, to obtain higher rates of heat dissipation, and is configured to dissipate heat generated by ASIC 33. In alternative embodiments, heatsink 12 may also be cooled by a fluid.

FIG. 4 is a flow chart that schematically illustrates a method for fabricating electronic device 31, in accordance with an embodiment that is described herein.

The method begins at an IC die disposing operation 100 with disposing on surface 51 of interposer 32 (i) ASIC 33 and HBM 44, at distance 40 from one another, and (ii) dielectric layer 38 for filling areas on surface 51 that are not covered by IC dies or other components, as described in detail in FIG. 1 above.

At a groove forming operation 102, groove 76 is formed in dielectric layer 38, as described in detail in FIG. 3 above. In some embodiments, TIM layers 36 and 45 may be disposed on ASIC 33 and HBM 44, respectively, either before or after forming groove 76.

At a lid disposing operation 104, lid 22 is disposed on (i) laminate substrate 28, and (ii) TIM layer 45 and HBM 44, and confined section 77 is self-aligned into groove 76, as described in detail in FIG. 3 above. It is noted that lid 22 is not disposed over ASIC 33, as described in detail in FIG. 1 above.

In other embodiments, TIM layer 36 may be disposed on ASIC 33 after disposing lid 22 as described above. Moreover, after disposing lid 22 as described above, TIM layer 18 is disposed on the outer surface of lid 22, so as to improve the conductivity of heat between lid 22 and heat sink 12, as described in detail in FIG. 1 above.

At a heat sink disposing operation 106 that concludes the method, heat sink 12 is disposed on (i) TIM layer 36 and ASIC 33, and (ii) TIM layer 18, lid 22, and HBM 44, as described in detail in FIG. 1 above.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
first and second integrated circuit (IC) dies co-located on a surface of a substrate in proximity to each other;
a heat sink disposed on the first and second IC dies; and
a lid, which is disposed between the first IC die and the heat sink, and the lid is not disposed between the second IC die and the heat sink.

2. The electronic device according to claim 1, wherein the first IC die has (i) a first side, and (ii) a plurality of second sides, wherein the second IC die is positioned to face the first side of the first IC die, and wherein the lid is positioned to face at least one of the second sides of the first IC die.

3. The electronic device according to claim 1, wherein the heat sink has a stepped structure comprising: (i) a first surface configured to dissipate heat from the lid, and (ii) a second surface stepped from the first surface and configured to dissipate heat from the second die.

4. The electronic device according to claim 3, wherein the first and second IC dies are positioned side-by-side on the surface of the substrate, wherein the heat sink comprises a connection section connecting between the first surface and the second surface of the stepped structure, and wherein at least a portion of the connection section is placed in contact with the lid.

5. The electronic device according to claim 1, wherein the first IC die is configured to operate at a first temperature, and the second IC die is configured to operate at a second temperature, different from the first temperature, and comprising (i) a first thermal interface material (TIM) disposed between the first IC die and the lid, (ii) a second TIM disposed between the second IC die and the heat sink, wherein the first and second TIMs are separated from one another, and (iii) a structure formed between the first and second IC dies, and configured to reduce heat transfer between the first IC die and the second IC die.

6. The electronic device according to claim 5, and comprising a dam structure disposed between the first TIM and the second TIM, the dam structure being configured to reduce material transfer between the first TIM and the second TIM.

7. The electronic device according to claim 5, wherein the lid has a confining section disposed between the first TIM and the second TIM, the confining section being configured to reduce material transfer between the first TIM and the second TIM.

8. The electronic device according to claim 7, and comprising a groove formed in the structure between the first IC die and the second IC die, wherein the groove is configured to reduce heat transfer between the first IC die and the second IC die.

9. The electronic device according to claim 8, wherein the confining section of the lid is shaped to fit in at least part of the groove.

10. The electronic device according to claim 8, wherein the confining section of the lid is configured to self-align with the groove.

11. A method for fabricating an electronic device, the method comprising:
disposing, on a surface of a substrate, first and second integrated circuit (IC) dies co-located on the surface in proximity to each other;
disposing a heat sink on the first and second IC dies; and
disposing, between the first IC die and the heat sink, a lid, which is not disposed between the second IC die and the heat sink.

12. The method according to claim 11, wherein the first IC die has (i) a first side, and (ii) a plurality of second sides, wherein disposing the first and second IC dies comprising positioning the second IC die to face the first side of the first IC die, and wherein disposing the lid comprises positioning the lid to face at least one of the second sides of the first IC die.

13. The method according to claim 11, wherein disposing the heat sink comprises disposing a stepped structure comprising: (i) a first surface for dissipating heat from the lid, and (ii) a second surface stepped from the first surface for dissipating heat from the second die.

14. The method according to claim 13, wherein disposing the first and second IC dies comprises positioning the first and second IC dies side-by-side on the surface of the substrate, wherein the heat sink comprises a connection section connecting between the first surface and the second surface of the stepped structure, and wherein disposing the heat sink and the lid comprises placing at least a portion of the connection section of the heat sink in contact with the lid.

15. The method according to claim 11, wherein disposing the first and second IC dies comprises disposing the first IC die for operating at a first temperature, and disposing the second IC die for operating at a second temperature, different from the first temperature, and comprising (i) disposing, between the first IC die and the lid, a first thermal interface material (TIM), (ii) disposing, between the second IC die and the heat sink, a second TIM, wherein the first and second TIMs are separated from one another, and (iii) forming, between the first and second IC dies, a structure for reducing heat transfer between the first IC die and the second IC die.

16. The method according to claim 15, and comprising disposing, between the first TIM and the second TIM, a dam structure for reducing material transfer between the first TIM and the second TIM.

17. The method according to claim 15, wherein the lid has a confining section, and disposing the lid comprises disposing, between the first TIM and the second TIM, the confining section for reducing material transfer between the first TIM and the second TIM.

18. The method according to claim 17, and comprising forming in the structure between the first IC die and the second IC die, a groove for reducing heat transfer between the first IC die and the second IC die.

19. The method according to claim 18, wherein the confining section of the lid is shaped to fit in at least part of the groove, and wherein disposing the lid comprises disposing the confining section to fit in the at least part of the groove.

20. The method according to claim 18, disposing the confining section comprises disposing the confining section to self-align with the groove.
